(19) United States
(12) Patent Application Publication
(10) Pub. No.: US 2014/0144495 A1
(43) Pub. Date: May 29, 2014

(54) SOLAR CELL AND METHOD FOR MANUFACTURING THE SAME

(71) Applicants: NATIONAL UNIVERSITY CORPORATION TOKYO UNIVERSITY OF AGRICULTURE AND TECHNOLOGY, Fuchu-shi, Tokyo (JP); NISSIN ELECTRIC CO., LTD., Kyoto-shi, Kyoto (JP)

(72) Inventors: Toshiyuki Sameshima, Tokyo (JP); Yasunori Ando, Kyoto (JP)

(21) Appl. No.: 14/131,205

(22) PCT Filed: Feb. 3, 2012
(86) PCT No.: PCT/JP2012/052464

§ 371 Date: Jan. 7, 2014

(30) Foreign Application Priority Data
Jul. 11, 2011 (JP) 2011-152562

(51) Int. Cl. H01L 31/18; H01L 31/077

(52) U.S. Cl. CPC H01L 31/1824; H01L 31/077
USPC 136/255; 438/87

(57) ABSTRACT

Disclosed is a method for manufacturing a solar cell having a structure wherein a silicon thin film (52) is formed on a crystalline silicon substrate (50). The manufacturing method is provided with: a thin film forming step, wherein, as a silicon thin film (52), a microcrystalline silicon thin film containing a fine silicon crystal is formed on the crystalline silicon substrate (50) by means of an inductively-coupled plasma CVD in which plasma is generated by inductive coupling; and a water vapor thermal treatment step, wherein the substrate having the microcrystalline silicon thin film formed thereon is thermal-treated under water vapor atmosphere under a pressure of 5×10⁵ Pa or more.

### BACKGROUND OF THE INVENTION

1. Field of the Invention

The present invention generally relates to a so-called hybrid type solar cell having a structure in which a silicon thin film is formed on a crystalline silicon substrate and a method for manufacturing the same.

2. Description of Related Art

As an example of solar cells having a structure in which an amorphous silicon thin film is laminated on a crystalline silicon substrate, a solar cell having the following structure is well known: an i-type (i.e., intrinsic) amorphous silicon thin film formed on each of two sides of the crystalline silicon substrate, a p-type amorphous silicon thin film formed on a surface of one of the i-type amorphous silicon thin films, and an n-type amorphous silicon thin film formed on a surface of the other of the i-type amorphous silicon thin films (e.g., see Patent Document 1).

A transparent conductive film and comb-shaped electrodes for outputting the photocurrent are formed further outside the p-type amorphous silicon thin film and the n-type amorphous silicon thin film respectively.

Conventionally, the amorphous silicon thin films are formed in the following way: the silane gas (SiH₄) and hydrogen gas (H₂) are used as source gases and, by means of a capacitively-coupled plasma chemical vapor deposition (CVD) process in which plasma is generated by capacitive coupling, the gases are deposited on the substrate through discharge decomposition. Furthermore, during formation of the p-type and the n-type doped thin films, small amounts of diborane (B₂H₆) or phosphine (PH₃) are mixed in the source gas.

The following scheme has been known: on the crystalline silicon substrate, the aforesaid i-type amorphous silicon thin films not doped with impurities are interposed between the crystalline silicon substrate and the p-type and the n-type amorphous silicon thin films, which serve as contact layers, to prolong the carrier lifetime on the interfaces. In this way, the open-circuit voltage of the solar cell can be increased and the conversion efficiency can be improved.

### PRIOR ART DOCUMENT

### Patent Document

Patent Document 1: Japanese Patent Publication No. Heisei 10-135497 (paragraphs 0038-0040, and FIG. 4)

### SUMMARY OF THE INVENTION

### Problem to be Solved by the Invention

As is widely known in terms of physical properties of amorphous silicon, hydrogen in the thin film can compensate dangling bonds in the silicon, and this greatly contributes to revealing characteristics and improving performances of the silicon as a kind of semiconductor. Therefore, for the interface between the crystalline silicon and the amorphous silicon thin film, hydrogen is also greatly helpful for the interface both during the film formation and after the film formation.

However, an excessive amount of hydrogen may lead to defects, which will shorten the carrier lifetime. Consequently, it becomes an important task that the hydrogen concentration distribution in the crystalline silicon/the i-type thin film/the doped (p-type, n-type) thin films needs to be in an ingenious profile and the control of the film forming process is very difficult.

Moreover, for the capacitively-coupled plasma CVD process that is conventionally used as a film forming process, a high voltage is generally applied to the plasma, so that the electric potential of the plasma is high. As a result, ions incident on the substrate surface have a high energy, and the impact of the ions towards the interface between the substrate and the thin film and, during the film forming process, towards the thin film surface is great. This leads to a problem that defects tend to be generated on the interface and in the deposited thin film to shorten the carrier lifetime.

Further, in the capacitively-coupled plasma CVD process, the efficiency of decomposing the gas through high-frequency discharging is low. Accordingly, an excessive amount of hydrogen will be contained in the thin film in the film forming step that uses silane, which is a kind of hydride, and hydrogen as the source material. This is also a main factor that shortens the carrier lifetime.

Accordingly, a primary objective of the present invention is to provide a method for manufacturing a solar cell, which can form a thin film that has fewer defects and does not contain excessive hydrogen during the film formation and, after the film formation, further repair the defects generated during the film formation to reduce the defects on the interface and in the thin film. In this way, a long carrier lifetime can be achieved.

### Means to Solve the Problem

The manufacturing method of the present invention is a method for manufacturing a solar cell that has a structure in which a silicon thin film is formed on a crystalline silicon substrate, the method for manufacturing the solar cell comprising: a thin film forming step, wherein a microcrystalline silicon thin film containing a fine silicon crystal is formed on the crystalline silicon substrate as the silicon thin film by means of an inductively-coupled plasma chemical vapor deposition (CVD) process in which plasma is generated by inductive coupling; and a water vapor thermal treatment step, wherein the substrate having the microcrystalline silicon thin film formed thereon is thermal-treated under water vapor atmosphere under a pressure of 5×10⁵ Pa or more.

Preferably, a temperature of the crystalline silicon substrate in the thin film forming step is set to 100° C.-300° C.

Preferably, in the water vapor thermal treatment step, a temperature is set to 150° C.-300° C., a water vapor pressure is set to 5×10⁵ Pa-1.5×10⁶ Pa, and a treatment duration is set to 0.5 hour-3 hours.

When the solar cell has a structure in which an i-type silicon thin film is formed on each of two sides of the crystalline silicon substrate, a p-type silicon thin film is formed on a surface of one of the i-type silicon thin films and an n-type silicon thin film is formed on a surface of the other of the i-type silicon thin films, microcrystalline silicon thin films of corresponding types may also be formed as at least one of the i-type silicon thin films, the p-type silicon thin film and the n-type silicon thin film through the thin film forming step, and then the water vapor thermal treatment step is performed.

When the solar cell has a structure in which an i-type silicon thin film is formed on the crystalline silicon substrate, and a first electrode and a second electrode having work functions different from each other are formed on the silicon thin film, microcrystalline silicon thin films of the i-type may also be formed as the i-type silicon thin films through the thin film forming step, and then the water vapor thermal treatment step is performed.

### Effects of the Present Invention

According to the invention as claimed in claim 1, the inductively-coupled plasma CVD is used in the thin film forming step, so the gas decomposition efficiency is high and the electric potential of the plasma can be suppressed to be relatively low. Hence, a thin film that has fewer defects and does not contain excessive hydrogen can be formed during the film formation. Thereby, a long carrier lifetime can be achieved.

Further, through the water vapor thermal treatment performed after the film formation, defects generated during the film formation can be repaired to reduce the defects on the interface and in the thin film. Thereby, a longer carrier lifetime can be achieved.

Further, through combining the formation of the microcrystalline silicon thin film and the water vapor thermal treatment, a longer carrier lifetime can be achieved as compared with the case where the formation of an amorphous silicon thin film and the water vapor thermal treatment are combined.

Further, unlike the aforesaid conventional technology where the hydrogen concentration distribution on the interface has to be controlled delicately, a very long carrier lifetime can be achieved by simply forming a microcrystalline silicon thin film on the crystalline silicon substrate and performing the water vapor thermal treatment.

As a result of prolonging the carrier lifetime as described above, a solar cell having a high open-circuit voltage and high conversion efficiency can be obtained.

According to the invention as claimed in claim 2, the following effect can be further obtained. That is, by setting the temperature of the crystalline silicon substrate in the thin film forming step to 100° C.-300° C., separation and diffusion of hydrogen in the thin film during the film formation can be suppressed to form a microcrystalline silicon thin film having fewer defects. Thereby, a longer carrier lifetime can be achieved.

According to the invention as claimed in claim 3, the following effect can be further obtained. That is, by setting the temperature to 150° C.-300° C., the water vapor pressure to 5×10⁵ Pa-1.5×10⁶ Pa and the treatment duration to 0.5 hour-3 hours in the water vapor thermal treatment step, the effect of the water vapor thermal treatment described above can be effectively exerted.

According to the invention as claimed in claim 4, the following effect can be further obtained. That is, the main purpose of the i-type silicon thin films in the solar cell is to prolong the carrier lifetime on the interface by preventing diffusion of impurities from the silicon thin film that has been doped into the p-type or the n-type. By forming microcrystalline silicon thin film of the i-type as the i-type silicon thin films through the thin film forming step and then performing the water vapor thermal treatment step, defects on the interface and in the thin film can be reduced as described above to prolong the carrier lifetime. Accordingly, the aforesaid main purpose of the i-type silicon thin films can be achieved more effectively.

According to the inventions as claimed in claim 5 and claim 6, the following effect can be further obtained. That is, the amorphous silicon thin film doped with n-type or p-type impurities has a problem for having difficulties in forming a low resistivity film because of the low activation rate of impurities. If an increased amount of impurities is used in order to achieve a low resistivity, defects caused by the impurities may shorten the carrier lifetime. In contrast, the microcrystalline silicon thin film doped with n-type or p-type impurities allows for a high activation rate of impurities, so a low resistivity film can be formed by using only a small amount of impurities. Therefore, possibilities of forming defects can be reduced so that a solar cell having a high open-circuit voltage, a large short-circuit current and high conversion efficiency can be obtained.

According to the invention as claimed in claim 7, the following effect can be further obtained. That is, by forming microcrystalline silicon thin films of the i-type as the i-type silicon thin film through the thin film forming step and then performing the water vapor thermal treatment step, defects on the interface and in the thin film can be reduced as described above to prolong the carrier lifetime. Accordingly, a solar cell having high conversion efficiency can be obtained.

According to the invention as claimed in claim 8, a solar cell having high conversion efficiency can be achieved for the aforesaid reasons.

### BRIEF DESCRIPTION OF THE DRAWINGS

FIG. 1 is a cross-sectional view illustrating an example of an inductively-coupled plasma CVD apparatus that can be used for the thin film forming step.

FIG. 2 is a cross-sectional view illustrating an example of a sample in which a silicon thin film is formed on a crystal substrate.

FIG. 3 is a graph illustrating an example of testing results of carrier lifetime of photo-induced carriers in samples obtained through various treatments.

FIG. 4 is a graph illustrating an example of testing results of the Raman scattering spectrum of silicon thin films on sample surfaces.

FIG. 5 is a schematic cross-sectional view illustrating an example of a hybrid type solar cell.

FIG. 6 is a schematic cross-sectional view illustrating another example of the hybrid type solar cell.

### DESCRIPTION OF THE EMBODIMENTS

The manufacturing method of the present invention is a method for manufacturing a solar cell having a structure in which a silicon thin film is formed on a crystalline silicon substrate (e.g., a structure in which a silicon thin film 52 is formed on a crystalline silicon substrate 50 as shown in FIG. 2). The manufacturing method comprises: a thin film forming step, wherein a microcrystalline silicon thin film containing a fine silicon crystal is formed on the crystalline silicon substrate as the silicon thin film, by means of an inductively-coupled plasma chemical vapor deposition (CVD) process in which plasma is generated by inductive coupling; and a water vapor thermal treatment step, wherein the substrate having the microcrystalline silicon thin film formed thereon is thermal-treated under water vapor atmosphere under a pressure of 5×10⁵ Pa or more.

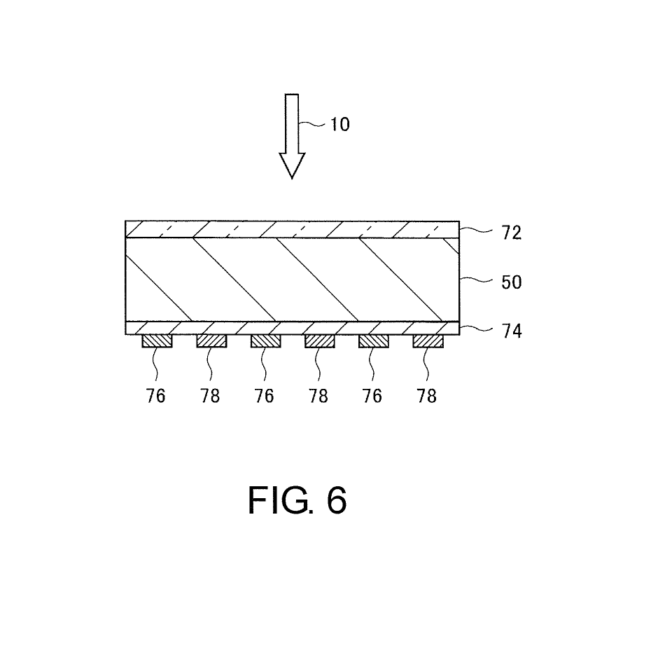

By “a silicon thin film is formed on a crystalline silicon substrate”, it refers to the following two cases: a case where the silicon thin film is formed directly on a surface of the crystalline silicon substrate without any other intervening thin film therebetween, and a case where the silicon thin film is formed on the surface of the crystalline silicon substrate via an intervening thin film therebetween. Therefore, in the thin film forming step described above, it is possible that the microcrystalline silicon thin film is formed directly on the surface of the crystalline silicon substrate without any intervening layers therebetween or the microcrystalline silicon thin film is formed on the surface of the crystalline silicon substrate via an intervening thin film therebetween. For example, forming microcrystalline silicon thin films as a silicon thin film 52 shown in FIG. 2, as silicon thin films 54, 56 shown in FIG. 5, or as a silicon thin film 74 shown in FIG. 6 is a more specific example of the former case; and forming microcrystalline silicon thin films as silicon thin films 58, 60 shown in FIG. 5 is a more specific example of the latter case.

The crystalline silicon substrate may either be a monocrystalline silicon substrate or a polycrystalline silicon substrate. The crystalline silicon substrate may have conductivity of either the p-type or the n-type.

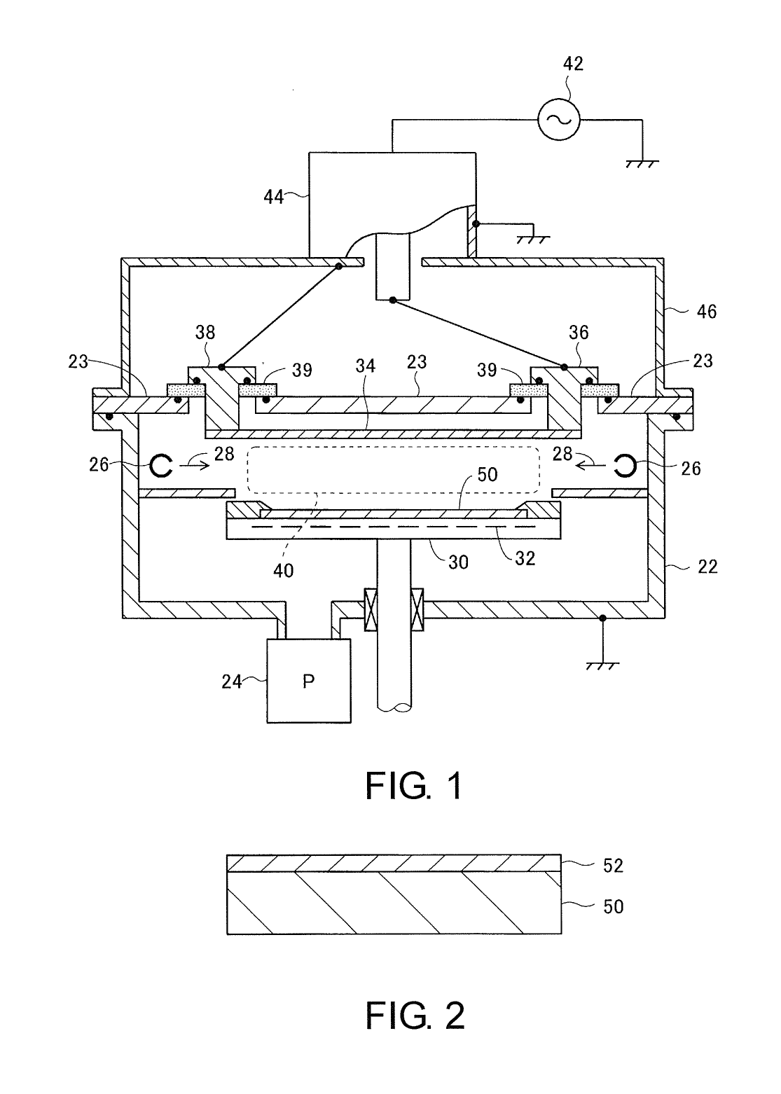

In the thin film forming step described above, for example, a plasma CVD apparatus shown in FIG. 1 may be used.

The plasma CVD apparatus is an inductively-coupled plasma CVD apparatus as described hereinbelow, in which plasma 40 is generated by means of an electric field induced by a high-frequency (HF) current flowing from an HF power source 42 through a planar conductor (in other words, a planar antenna, which is also applied hereinafter) 34 and the plasma 40 is used to form a thin film on the substrate 50 through an inductively-coupled plasma CVD process.

Specifically, the substrate 50 is the crystalline silicon substrate described above.

The plasma CVD apparatus comprises a vacuum container 22 made of, for example, a metal. The interior of the vacuum container 22 is vacuumized by a vacuum pumping apparatus 24.

Into the vacuum container 22, a source gas 28 corresponding to the treatment to be performed on the substrate 20 is introduced through a gas feeding pipe 26. The source gas 28 is, for example, a silane gas (precisely speaking, a monosilane gas SiH₄) or a silane gas that has been diluted by hydrogen or by a noble gas (e.g., helium, neon, argon or the like). The doping of impurities will be described later.

A holder 30 for holding the substrate 50 is disposed in the vacuum container 22. A heater 32 for heating the substrate 50 to a desired temperature is disposed in the holder 30.

In the vacuum container 22, and more specifically, at an inner side of a top surface 23 of the vacuum container 22, the planar conductor 34 in a rectangular planar form is disposed to face a substrate holding surface of the holder 30. The planar form of the planar conductor 34 may be either a rectangular form or a square form. The specific planar four to be adopted can be determined, for example, by the planar form of the substrate 50.

From an HF power source 42 and via a matching circuit 44 as well as a power feeding electrode 36 and a terminal electrode 38, HF electric power is supplied between a power feeding terminal, which is located at one end of the planar conductor 34 in the length direction, and a terminal located at the other end. Then, an HF current flows through the planar conductor 34. The frequency of the HF electric power output from the HF power source 42 is, for example, the typical frequency of 13.56 MHz, although it is not limited thereto.

The power feeding electrode 36 and the terminal electrode 38 are installed on a top surface 23 of the vacuum container 22 by means of insulation flanges 39 respectively. Packing for vacuum sealing is respectively disposed between these elements. Preferably, an upper portion of the top surface 23 is, as in this example, covered in advance by a shielding box 46 for preventing HF leakage.

By means of the HF current that flows through the planar conductor 34 as described above, an HF magnetic field is generated around the planar conductor 34 so that an induced electric field is generated in a direction opposite to the HF current. With the induced electric field, electrons are accelerated in the vacuum container 22 to ionize the gas 28 near the planar conductor 34 so that plasma 40 is generated near the planar conductor 34. The plasma 40 diffuses to nearby the substrate 50 and, by means of the plasma 40, a thin film can be formed on the substrate 50 through an inductively-coupled plasma CVD process.

More specifically, a microcrystalline silicon thin film containing fine silicon crystals can be formed on the crystalline silicon substrate 50.

The microcrystalline silicon thin film formed through the plasma CVD process as described above contains hydrogen, so strictly it should be called as a hydrogenated microcrystalline silicon (μc-Si:H or nc-Si:H) thin film. This also applies to the microcrystalline silicon thin films to be described hereinbelow.

In order to form a microcrystalline silicon thin film, instead of an amorphous silicon thin film, on the crystalline silicon substrate 50, it will suffice to generate more hydrogen radicals in the plasma 40 to facilitate crystallization of silicon. Specifically, methods such as the followings may be adopted: increasing the amount of HF electric power fed from the HF power source 42; setting the gas pressure in the vacuum container 22 to be relatively low so that hydrogen radicals generated can reach the surface of the substrate 50 easily; and increasing the partial pressure of hydrogen in the vacuum container 22.

The inductively-coupled plasma CVD process used in the thin film forming step can generate a high-strength induced electric field in the plasma. Therefore, as compared with the capacitively-coupled plasma CVD process, the gas decomposition efficiency is high and a thin film without containing excessive hydrogen can be formed.

Furthermore, the inductively-coupled plasma CVD process generates plasma by having an HF current flow through an antenna to generate an induced electric field, so that the electric potential of the plasma can be suppressed to be relatively low and the impact of ions towards the substrate surface and the deposited thin film can be reduced as compared with the capacitvely-coupled plasma CVD process that generates plasma by applying an HF voltage between two parallel electrodes to generate an HF electric field between the two electrodes. As a result, defects generated on the interface with the substrate and in the deposited thin film can be reduced.

With the aforesaid mechanisms, a long carrier lifetime can be achieved.

Further, through the water vapor thermal treatment performed after the film formation, the defects generated during the film formation can be repaired to reduce the defects on the interface and in the thin film. In this way, a longer carrier lifetime can be achieved.

Furthermore, it has been ascertained through experiments that, through the combination of the formation of the microcrystalline silicon thin film and the water vapor thermal treatment, a longer carrier lifetime can be achieved as compared with the case where the formation of an amorphous silicon thin film and the water vapor thermal treatment are combined. This will be detailed later.

As a result of prolonging the carrier lifetime as described above, a solar cell having a high open-circuit voltage and high conversion efficiency can be obtained.

Preferably, by setting the temperature of the crystalline silicon substrate in the thin film forming step to be a relatively low temperature of 100° C.-300° C., separation and diffusion of hydrogen in the thin film during the film formation can be suppressed to form a microcrystalline silicon thin film having fewer defects. Thereby, a longer carrier lifetime can be achieved.

Preferably, by setting the temperature to 150° C.-300° C., the water vapor pressure to 5×10⁵ Pa-1.5×10⁶ Pa and the treatment duration to 0.5 hour-3 hours in the water vapor thermal treatment step, the effect of the water vapor thermal treatment described above can be effectively obtained.

Next, experimental results of performing film formation and processing in different ways on a surface of a crystalline silicon substrate and measuring the carrier lifetime in the thus obtained sample will be described.

As shown in FIG. 2, the silicon thin film 52 was formed on the crystalline silicon substrate 50. In this case, a monocrystalline silicon substrate was used for the crystalline silicon substrate 50. During formation of the silicon thin film 52, the inductively-coupled plasma CVD apparatus (i.e., an inductively-coupled plasma CVD process) as shown in FIG. 1 was used. For the source material 28, 100% of silane gas (SiH₄) was used. The temperature of the substrate 50 was set to 150° C. during the film formation.

Furthermore, the carrier lifetimes of carriers on interfaces of the sample and of other control samples were measured by using the photo-induced carrier microwave absorption method. More specifically, the effective life times of photo-induced minor carriers when light having a central wavelength of 620 nm and a light intensity of 1.5 mW/cm² was irradiated on a surface of the sample from a light emitting diode (LED) were measured.

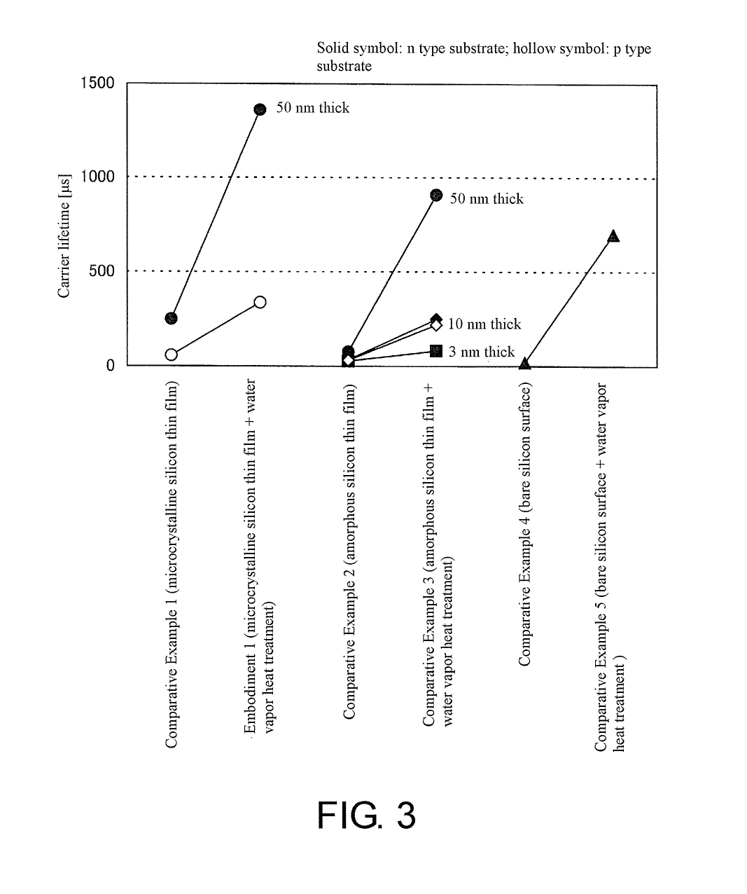

The results are summarized in Table 1, and the contents of Table 1 are plotted in FIG. 3.

TABLE 1
Carrier lifetime [μs]

| | | | | | Comparative | | |
|---|---|---|---|---|---|---|---|
| | | | | | Example 3 | | Comparative |
| | | | Embodiment 1 | | (amorphous | | Example 5 |
| | | | (Microcrystalline | | Si thin film + | | (bare Si |
| | | Comparative | Si thin film + | Comparative | water | Comparative | surface + |
| | Film | Example 1 | water vapor | Example 2 | vapor | Example 4 | water vapor |
| | thickness | (Microcrystalline | thermal | (Amorphous | thermal | (bare Si | thermal |
| | [nm] | Si thin film) | treatment) | Si thin film) | treatment) | surface) | treatment) |
| n-type | 50 | 250 | 1360 | | | | |
| substrate | 50 | | | 78 | 910 | | |
| | 10 | | | 35 | 250 | | |
| | 3 | | | 27 | 82 | | |
| | | | | | | 20 | 700 |
| p-type | 50 | 58 | 338 | | | | |
| substrate | 10 | | | 32 | 220 | | |

Firstly, a case where the crystalline silicon substrate 50 is of the n-type will be described. This case is indicated by solid symbols in FIG. 3.

On the surface of the crystalline silicon substrate 50 where the natural oxide film had been removed by diluted hydrofluoric (HF) acid (i.e., on a bare silicon surface), the carriers had a carrier lifetime of 20 μs (Comparative Example 4). On a same crystalline silicon substrate 50 that had been subjected to the water vapor thermal treatment described above, the carriers had a carrier lifetime of 700 μs (Comparative Example 5).

In the water vapor thermal treatment step, the temperature was 210° C., the water vapor pressure was 1×10⁵ Pa, and the duration was 3 hours. This was also the same for Comparative Example 3 and Embodiment 1 to be described later.

When an amorphous silicon thin film was formed as the silicon thin film 52 on a surface of a crystalline silicon substrate 50 where the natural oxide film had also been removed, the carrier lifetime on the interface was 27 is for a film thickness of 3 nm, 35 μs for a film thickness of 10 nm and 78 μs for a film thickness of 50 nm (Comparative Example 2).

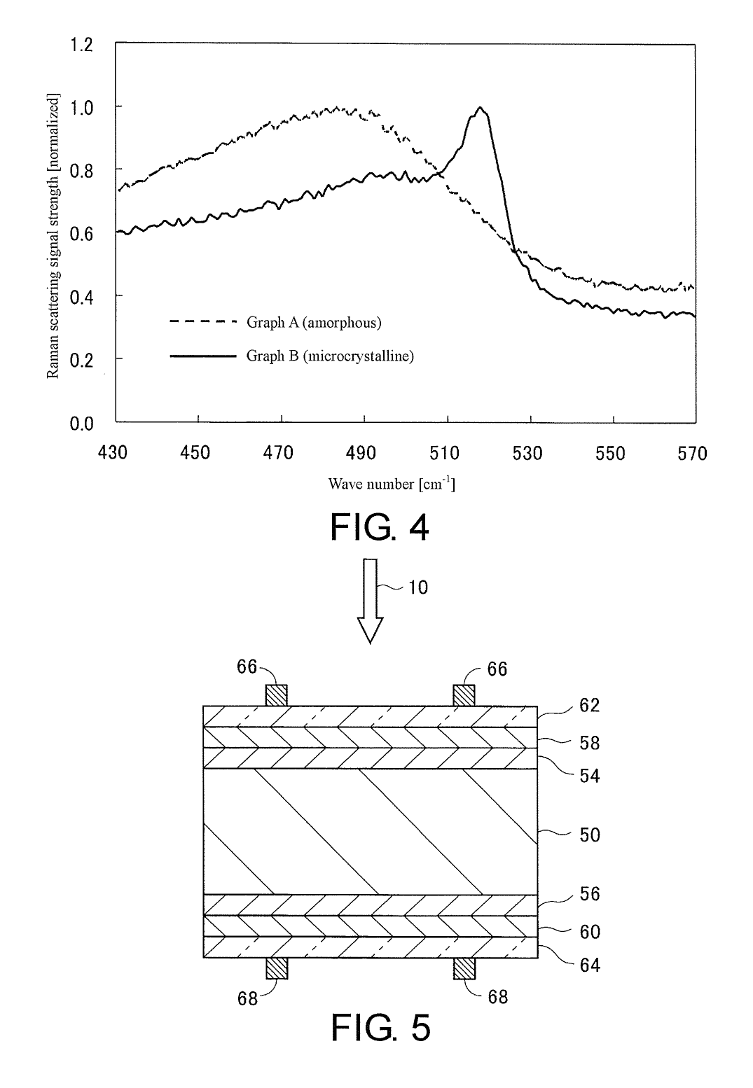

The Raman scattering spectrum of the silicon thin film 52 having a film thickness of 50 nm was measured through Raman spectroscopy, and results of which are as shown by graph A in FIG. 4. No peak representing crystalline silicon was found at positions around the wave number 520 cm⁻¹, and only a relatively wide peak that represents amorphous silicon was found around the wave number 480 cm⁻¹.

For a sample that was identical to that of Comparative Example 2 but had been subjected to the water vapor thermal treatment described above, the carrier lifetime was 82 μs for a film thickness of 3 nm, 250 μs for a film thickness of 10 nm and 910 μs for a film thickness of 50 nm (Comparative Example 3).

When a microcrystalline silicon thin film having a film thickness of 50 nm was formed as the silicon thin film 52 on a surface of a crystalline silicon substrate 50 where the natural oxide film had also been removed, the carrier lifetime on the interface was 250 μs (Comparative Example 1).

The Raman scattering spectrum of the silicon thin film 52 was measured through Raman spectroscopy, results of which are as shown by graph B in FIG. 4. A peak representing crystalline silicon was found at positions around the wave number 520 cm⁻¹.

For a sample that was identical to that of Comparative Example 1 but had been subjected to the water vapor thermal treatment described above, the carrier lifetime was 1360 μs (Embodiment 1).

As can be known from the aforesaid results, by forming a microcrystalline silicon thin film on the crystalline silicon substrate 50 through an inductively-coupled plasma CVD process, even with the same film thickness, a carrier lifetime (250 μs) of carriers longer than that (78 μs) of carriers on the interface where an amorphous silicon thin film was formed can be obtained. Although the reason is still unclear, such results were ascertained through experiments.

Further, by performing the formation of the microcrystalline silicon thin film through inductively-coupled plasma CVD process and the water vapor thermal treatment in combination as in Embodiment 1, it is ascertained that a very long carrier lifetime (1360 μs) can be achieved. That is, a longer carrier lifetime can be achieved as compared with the case where the bare silicon surface and the water vapor thermal treatment are combined (Comparative Example 5) and also with the case where the formation of the amorphous silicon thin film and the water vapor thermal treatment are combined (Comparative Example 3).

Furthermore, unlike the conventional technology where hydrogen concentration on the interface has to be controlled delicately, a very long carrier lifetime can be achieved by the simple process of forming a microcrystalline silicon thin film on the crystalline silicon substrate and then performing the water vapor thermal treatment.

Next, a case where the crystalline silicon substrate 50 is of the p-type will be described. This case is indicated by hollow symbols in FIG. 3.

When a 10 nm-thick amorphous silicon thin film was formed as the silicon thin film 52 through an inductively-coupled plasma CVD process on the surface of the crystalline silicon substrate 50 where the natural oxide film had also been removed as described above, the carriers had a carrier lifetime of 32 μs (Comparative Example 2). For a same sample that had been further subjected to the water vapor thermal treatment, the carriers had a carrier lifetime of 220 μs (Comparative Example 3).

Furthermore, when a 50 nm-thick microcrystalline silicon thin film was foamed as the silicon thin film 52 through an inductively-coupled plasma CVD process on the surface of the crystalline silicon substrate 50 where the natural oxide film had also been removed as described above, the carriers had a carrier lifetime of 58 μs (Comparative Example 1); and for a same sample that had been further subjected to the water vapor thermal treatment, the carriers had a carrier lifetime of 338 μs (Embodiment 1). That is, in this case, by performing the formation of the microcrystalline silicon thin film through the inductively-coupled plasma CVD process and the water vapor thermal treatment in combination, a long carrier lifetime can also be achieved.

Next, more specific examples of a solar cell structure suitable for the manufacturing method of the present invention will be described. The following examples all relate to the hybrid type solar cells.

The basic structure of the solar cell shown in FIG. 5 has been widely known (e.g., see Patent Document 1). The solar cell has a structure in which i-type silicon (i.e., intrinsic silicon without being doped with any impurities, and this applies also hereinbelow) thin films 54, 56 are formed on two sides of the crystalline silicon substrate 50, respectively, a p-type silicon thin film 58 is formed on a surface of one of the i-type silicon thin films 54 and an n-type silicon thin film 60 is formed on a surface of the other i-type silicon thin film 56. Further, transparent conductive films 62, 64 are formed on surfaces of the silicon thin films 58, 60, respectively, and comb-shaped electrodes 66, 68 for outputting the photocurrent are formed on outer surfaces of the transparent conductive films 62, 64, respectively. The crystalline silicon substrate 50 is generally of the n-type, but may also be of the p-type. Light 10 is incident from, for example, the side of the transparent conductive film 62.

In the method for manufacturing a solar cell of this structure, for example, it is also possible that: (a) microcrystalline silicon thin films of the i-type are formed as the i-type silicon thin films 54, 56 through the thin film forming step, and then the water vapor thermal treatment step is performed; (b) a microcrystalline silicon thin film of the p-type and a microcrystalline silicon thin film of the n-type are formed respectively as the p-type silicon thin film 58 and the n-type silicon thin film 60 respectively through the thin film forming step, and then the water vapor thermal treatment step is performed; and (c) microcrystalline silicon thin films of the i-type are formed as the i-type silicon thin films 54, 56, and a microcrystalline silicon thin film of the p-type and a microcrystalline silicon thin film of the n-type are respectively formed as the p-type silicon thin film 58 and the n-type silicon thin film 60 all through the thin film forming step, and then the water vapor thermal treatment step is performed. Additionally, for films other than what described in (a) to (c), they can be formed by conventional film forming technologies.

In case of forming doped silicon thin films 58, 60, the silicon thin films 58, 60 can be formed by mixing a desired dopant in the source gas 28 in advance. For example, a p-type silicon thin film 58 can be formed by mixing an appropriate amount of diborane (B₂H₆) in the source gas in advance, and an n-type silicon thin film 60 can be formed by mixing an appropriate amount of phosphine (PH₃) in the source gas in advance.

Film formation on the crystalline silicon substrate 50 may be performed on one side at a time or on both sides simultaneously. Specifically, this may be determined depending on the structure of the apparatus for film formation.

An example of an overall manufacturing process that performs film formation on one side at a time is as follows: crystalline silicon substrate 50→forming the i-type silicon thin film 54→forming the i-type silicon thin film 56→forming the p-type silicon thin film 58→forming the n-type silicon thin film 60→forming the transparent conductive film 62→forming the transparent conductive film 64→forming the electrode 66→forming the electrode 68→the water vapor thermal treatment. However, it is not merely limited thereto.

An example of an overall manufacturing process that performs film formation on both sides simultaneously is as follows: crystalline silicon substrate 50→forming the i-type silicon thin films 54, 56→forming the p-type silicon thin film 58→forming the n-type silicon thin film 60→forming the transparent conductive films 62, 64→forming the electrode 66→forming the electrode 68→the water vapor thermal treatment. However, it is not merely limited thereto.

The main purpose of the i-type silicon thin films 54, 56 in the solar cell described above are to prolong the carrier lifetime on the interface by preventing diffusion of impurities from the silicon thin films 58, 60 that have been doped into the p-type or the n-type. By forming microcrystalline silicon thin films of the i-type as the i-type silicon thin films 54, 56 through the thin film forming step and then performing the water vapor thermal treatment step as described in (a), defects on the interface and in the thin film can be reduced as described above to prolong the carrier lifetime. Accordingly, the aforesaid main purpose of the i-type silicon thin films 54, 56 can be achieved more effectively.

Furthermore, as described in Description of Related Art, conventionally amorphous silicon thin films doped into the n-type or the p-type are formed as the silicon thin films 58, 60. The amorphous silicon thin films doped into the n-type or the p-type have a problem that it is difficult to form a low resistivity film because of the low activation rate of impurities. If an increased amount of impurities is used in order to achieve a low resistivity, defects may be caused by the impurities to shorten the carrier lifetime. In contrast, forming microcrystalline silicon thin films doped into the n-type or the p-type as the silicon thin films 58, 60 as described in (b) or (c) allows for a high activation rate of impurities, so that a low resistivity film can be formed by using only a small amount of impurities. Therefore, possibilities of forming defects can be reduced, so a solar cell having a high open-circuit voltage, a large short-circuit current and high conversion efficiency can be obtained.

A solar cell shown in FIG. 6 has a structure in which an i-type silicon thin film 74 is formed on one surface of the crystalline silicon substrate 50 and a first electrode 76 and a second electrode 78 having work functions different from each other are formed on the silicon thin film 74. The two electrodes 76, 78 are, for example, comb-shaped. On the other surface of the crystalline silicon substrate 50, a transparent protective film 72 formed from a silicon oxide film, a silicon nitride film or the like is formed. The crystalline silicon substrate 50 may be either of the n-type or the p-type. Light 10 is incident from the side of the transparent protective film 72 in this example.

The first electrode 76 is formed of a metal having a work function smaller than those of the crystalline silicon substrate 50 and the second electrode 78, such as, aluminium (Al), hafnium (Hf), tantalum (Ta), indium (In), zirconium (Zr) or the like. The second electrode 78 is foamed of a metal having a work function greater than those of the crystalline silicon substrate 50 and the first electrode 76, such as, gold (Au), nickel (Ni), platinum (Pt), palladium (Pd) or the like.

In this solar cell, an MIS (metal/insulated thin film/semiconductor) structure is formed by the electrode 76, the silicon thin film 74 and the crystalline silicon substrate 50 and also an MIS structure is formed by the electrode 78, the silicon thin film 74 and the crystalline silicon substrate 50 to form a double-MIS structure. In this way, electric power can be generated efficiently owing to the work function difference between the electrode 76 and the electrode 78.

During manufacturing of the solar cell of this structure, a microcrystalline silicon thin film of the i-type is formed as the i-type thin film 74 through the thin film forming step and then the water vapor thermal treatment is performed. Additionally, the transparent protective film 72 may be formed by a conventional film forming technology.

An example of an overall manufacturing process of the solar cell is as follows: the crystalline silicon substrate 50→forming the transparent protective film 72→removing the oxide film from a lower surface (i.e., the surface at the side of the silicon thin film 74) of the crystalline silicon substrate 50→forming the silicon thin film 74→forming the electrode 76→forming the electrode 78→the water vapor thermal treatment. However, it is not limited thereto.

During manufacturing of the solar cell of this structure, a microcrystalline silicon thin film of the i-type is formed as the i-type thin film 74 through the thin film forming step and then the water vapor thermal treatment is performed. Thereby, defects on the interface and in the thin film can be reduced as described above to prolong the carrier lifetime. Accordingly, a solar cell having high conversion efficiency can be obtained.

For the aforesaid reasons, the solar cells manufactured by the aforesaid manufacturing methods can achieve high conversion efficiency.

### DESCRIPTION OF REFERENCE NUMERALS

10: light
22: vacuum container
23: top surface
24: vacuum pumping apparatus
26: gas feeding pipe
28: source gas
30: holder
32: heater
34: planar conductor
36: power feeding electrode
38: terminal electrode
39: insulation flange
40: plasma
42: high-frequency (HF) power source
44: matching circuit
46: shielding box
50: substrate
52, 74: silicon thin film
54, 56: i-type silicon thin film
58: p-type silicon thin film
60: n-type silicon thin film
62, 64: transparent conductive film
66, 68, 76, 78: electrode
72: transparent protective film

1. A method for manufacturing a solar cell having a structure in which a silicon thin film is formed on a crystalline silicon substrate, the method comprising:
a thin film forming step, wherein a microcrystalline silicon thin film containing a fine silicon crystal is formed on the crystalline silicon substrate as the silicon thin film by an inductively-coupled plasma chemical vapor deposition (CVD) process in which plasma is generated by inductive coupling; and
a water vapor thermal treatment step, wherein the substrate having the microcrystalline silicon thin film formed thereon is thermal-treated under a water vapor atmosphere with a pressure of 5×10⁵ Pa or more.

2. The method according to claim 1, wherein a temperature of the crystalline silicon substrate in the thin film forming step is set to 100° C.-300° C.

3. The method according to claim 1, wherein in the water vapor thermal treatment step, a temperature is set to 150° C.-300° C., a water vapor pressure is set to 5×10⁵ Pa-1.5×10⁶ Pa, and a treatment duration is set to 0.5 hour-3 hours.

4. The method according to claim 1, wherein:
the solar cell has a structure in which an i-type silicon thin film is formed on each of two sides of the crystalline silicon substrate, a p-type silicon thin film is formed on a surface of one of the i-type silicon thin films and an n-type silicon thin film is formed on a surface of the other of the i-type silicon thin films;
microcrystalline silicon thin films of the i-type are formed as the i-type silicon thin films through the thin film forming step, and
then the water vapor thermal treatment step is performed.

5. The method according to claim 1, wherein:
the solar cell has a structure in which an i-type silicon thin film is formed on each of two sides of the crystalline silicon substrate, a p-type silicon thin film is formed on a surface of one of the i-type silicon thin films and an n-type silicon thin film is formed on a surface of the other of the i-type silicon thin films;
a microcrystalline silicon thin film of the p-type and a microcrystalline silicon thin film of the n-type are formed as the p-type silicon thin film and the n-type silicon thin film, respectively, through the thin film forming step, and
then the water vapor thermal treatment step is performed.

6. The method according to claim 1, wherein:
the solar cell has a structure in which an i-type silicon thin film is formed on each of two sides of the crystalline silicon substrate, a p-type silicon thin film is formed on a surface of one of the i-type silicon thin films and an n-type silicon thin film is formed on a surface of the other of the i-type silicon thin films;
microcrystalline silicon thin films of the i-type are formed as the i-type silicon thin films, and a microcrystalline silicon thin film of the p-type and a microcrystalline silicon thin film of the n-type are formed as the p-type silicon thin film and the n-type silicon thin film, respectively all through the thin film forming step, and
then the water vapor thermal treatment step is performed.

7. The method according to claim 1, wherein:
the solar cell has a structure in which an i-type silicon thin film is formed on the crystalline silicon substrate, and a first electrode and a second electrode having work functions different from each other are formed on the silicon thin film,
microcrystalline silicon thin films of the i-type are formed as the i-type silicon thin films through the thin film forming step, and
then the water vapor thermal treatment step is performed.

8. A solar cell manufactured by the method according to claim 1.
